(19) United States
(12) Patent Application Publication
(10) Pub. No.: US 2010/0221901 A1
(43) Pub. Date: Sep. 2, 2010

(54) METHOD FOR PREPARING CADMIUM SULFIDE FILM

(75) Inventors: Zhiju Cai, Shenzhen (CN); Wenyu Cao, Shenzhen (CN); Yong Zhou, Shenzhen (CN)

Correspondence Address: BRINKS HOFER GILSON & LIONE, P.O. BOX 10395, CHICAGO, IL, 60610, US

(73) Assignee: BYD COMPANY LIMITED, Shenzhen (CN)

(21) Appl. No.: 12/712,881

(22) Filed: Feb. 25, 2010

(30) Foreign Application Priority Data
Feb. 27, 2009 (CN) 200910105671.3

(51) Int. Cl. H01L 21/20

(52) U.S. Cl. 438/492; 257/E21.091

(57) ABSTRACT

A method for preparing a cadmium sulfide film comprises: providing a slurry; coating a first substrate with the slurry; heating the first substrate to produce a vapor; and depositing the vapor on a second substrate to form a cadmium sulfide film. The slurry comprises a dispersant, cadmium particles and sulfur particles.

### CROSS-REFERENCE TO RELATED APPLICATIONS

This application claims priority to Chinese Patent Application No. 200910105671.3, filed Feb. 27, 2009, the entire contents of which are incorporated herein by reference.

### FIELD

The present disclosure relates to a method for preparing a cadmium sulfide film.

### BACKGROUND

Cadmium sulfide is a wide band gap semiconductor material with stable chemical performance. It can be used in solar cells, where the cadmium sulfide functions as an n-type semiconductor layer and absorbing layer. For example, it can form a p-n junction together with a p-type layer such as Cu(InGa)Se, CdTe and so on, and further can form a solar cell. In these cells, light transmitting through a cadmium sulfide layer is further absorbed by p type semiconductor near the p-n injunction. The performance of the cadmium sulfide layer directly affects the performance of the absorbing film prepared thereof. Therefore, cadmium sulfide is very important for the efficiency and lifespan of the solar cell.

At present, close-space-sublimation (CSS) is used by some to prepare cadmium sulfide films. Under a certain vacuum degree and in a protective atmosphere, source material particles, i.e. particles of cadmium sulfide, are heated in an evaporation container. The particles then sublime and deposit on a substrate with a relatively lower temperature, thereby forming a film on the substrate. The above method is easy to realize large scales and industrial productions. The production cost is relatively low and the depositing rate is high. Additionally, CSS is easy to be controlled. Therefore, it is a popular area in the film preparation research.

When preparing a cadmium sulfide film by CSS, the film is annealed, which is also mentioned as heat treatment. The film after annealing typically has an improved crystallinity and a decreased disfigurement density. Further, the electrical performance is improved and thereby the cell efficiency is improved.

Typically, the substrate is placed into an atmosphere containing cadmium chloride for annealing after deposition of cadmium sulfide. As cadmium chloride gas is toxic and may cause damages to a human body and cause pollution to the environment, the annealing device is required to have good air tightness. In addition, corrosive smoke and gas may be produced while cadmium chloride is decomposed under the high temperature. Therefore the annealing device is required to be corrosion resistant. Another annealing method may be adopted as follows: depositing a layer of cadmium chloride or a cadmium chloride methanol solution on the surface of cadmium sulfide layer, and annealing the substrate. The above treating methods have complex procedures which may decrease the producing efficiency and also may increase the cost.

Moreover, when preparing a cadmium sulfide film using the conventional CSS method, the utilization rate of the material is low, generally around 10%. In the CSS method, cadmium sulfide particles are placed into a crucible. After the crucible is covered, it may be difficult to add the exact amount of the source material into the crucible. The source material may be repeatedly used. In the repeatedly using process, the particle size, the particles density, and the chemical stoichiometry may change in the sublimation process and they may become difficult to control. With the repeated formation of the film layers, the thickness of the cadmium sulfide layer and the dispersion may increase accordingly. To reduce the dispersion, repeated usage of the source material needs to be limited accordingly. Therefore, the utilization rate of the source material is low, normally around 10%.

Utilization rate of the source material is calculated by dividing the total weight of source material film by the weight of the prepared cadmium sulfide film.

Further, as the CSS method requires vacuum conditions, the device operation needs to be stopped while the source material is added into the device. Under the same conditions, low utilization rates of the source material will increase the frequency of addition of the source material, which may lead to low production efficiency.

Moreover, when preparing a cadmium sulfide film by the CSS method, in a large-scale substrate, the film thickness of the center portion is larger than that of the edge portion. The source material at the central portion has a tendency of capturing the heat while the edge portion has a tendency of dissipating the heat. Thus, under the same conditions, the evaporation rate of the central source material is higher than that of the edge portion. In the same time period, the central portion of the substrate may have more source material deposition and the thickness is greater. Therefore, the thickness may not be uniform when producing a larger film. Typically, the central portion is thicker than the edge portion.

### BRIEF SUMMARY

In one aspect, a method for preparing a cadmium sulfide film comprises: providing a slurry; coating a first substrate with the slurry; heating the first substrate to produce a vapor; and depositing the vapor on a second substrate to form a cadmium sulfide film. The slurry comprises a dispersant, cadmium particles and sulfur particles.

In another aspect, a method for preparing a cadmium sulfide film, comprising: providing a slurry; coating a first substrate with the slurry to form a coating layer; drying the coating layer; heating the first substrate to produce a vapor; depositing the vapor onto a second substrate to form a cadmium sulfide film; and maintaining the cadmium sulfide film at a predetermined temperature thereby annealing the cadmium sulfide film. The slurry comprises a dispersant, cadmium particles and sulfur particles.

In yet another aspect, a method for preparing a cadmium sulfide film, comprising: providing a slurry; coating a first substrate with the slurry to form a coating layer; drying the coating layer; heating the first substrate to produce a vapor; depositing the vapor onto a second substrate to form a cadmium sulfide film; and maintaining the cadmium sulfide film at a predetermined temperature thereby annealing the cadmium sulfide film. The slurry comprises a dispersant, cadmium particles, sulfur particles, and cadmium chloride particles.

### BRIEF DESCRIPTION OF THE DRAWINGS

These and other aspects of the disclosure will become apparent and more readily appreciated from the following descriptions taken in conjunction with the drawings.

FIG. 1 is a cross sectional view of a close-space-sublimation device according to one embodiment of the disclosure;

FIG. 2 is a thickness distribution graph of a cadmium sulfide film prepared by the method of one embodiment of the disclosure; and

FIG. 3 is a thickness distribution graph of a cadmium sulfide film prepared according to prior art.

### DETAILED DESCRIPTION OF EMBODIMENTS OF THE DISCLOSURE

Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

According to an embodiment of the disclosure, a method for preparing a cadmium sulfide film is provided. The method comprises the following steps: providing a source material slurry; coating the slurry onto a first substrate to form a coating layer; heating the first substrate to produce a vapor; and depositing the vapor onto a surface of a second substrate to form a cadmium sulfide film. Preferably, the slurry is prepared by mixing cadmium particles and sulfur particles in a dispersant. Preferably, the slurry further comprises cadmium chloride. Preferably, the step of heating is performing in a closed space under a predetermined pressure in a protective atmosphere. Preferably, the pressure is about 10⁻³−10³ Pa.

The method can further include a step of annealing. The annealing is performed under a predetermined temperature for a predetermined time. The phrase “predetermined temperature” means a selected temperature or a selected temperature range. Preferably, the cadmium sulfide film is maintained at a temperature of between about 300 and about 450° C. for about 10 to about 40 minutes.

The method can further include a step of drying the coating layer. Preferably, the coating layer is dried at a temperature of between about 100 and about 250° C.

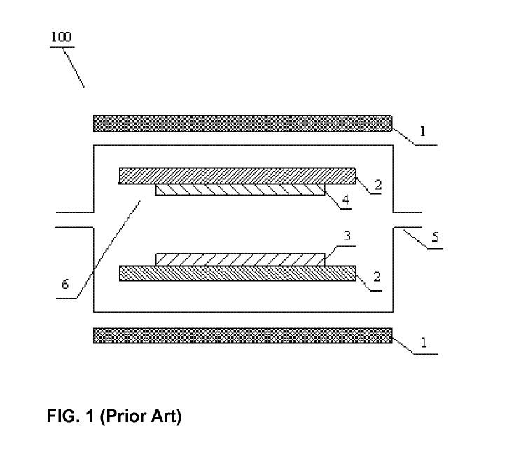

In the following the method of preparing the cadmium sulfide film will be described in detail in conjunction with the accompanying figures. FIG. 1 shows a schematic cross sectional view of a closed-space sublimation (CSS) device 100. In the CSS device, a pair of halogen tungsten lamps 1 are provided on the top and bottom of the device 100. The lamps 1 can heat the closed chamber 6. A pair of graphite plates 2 opposing each other are provided inside the device 100. The source material can be coated on the surface of the bottom plate. The top plate can heat the second substrate 4. There is a distance between the layer of source material and the substrate 2. A gas passage 5 at a side of the device 100 allows protective gases to flow in.

The method of the disclosure will be described in detail in the following in conjunction with the device 100 described above. A slurry is prepared by adding source materials and cadmium chloride particles into a dispersant. After the slurry is coated onto the bottom plate 2, the slurry is dried to form a coating layer. Then the closed space sublimation is performed under a pressure of about 10⁻³−10³ Pain the presence of protective gases. The evaporation chamber 6 is heated to sublimate the coating layer. The vapor is deposited as a film on the substrate 4.

After deposition, the film on the substrate 4 is annealed at a temperature for about 10-40 minutes.

According to one embodiment of the disclosure, the source material is a mixture of cadmium particles and sulfur particles. Preferably the molar ratio of cadmium to sulfur is about 1:1 to 1:1.1.

The use of cadmium particles and sulfur particles decreases the cost of source material, because pure cadmium sulfide is relatively expensive, and cadmium particles and sulfur particles are relatively cheap. In addition, the molar ratio of cadmium and sulfur may be adjusted so that the formed cadmium sulfide film may be rich in sulfur, which may enhance the compactness and light transmittance of the film, and therefore enhances the converting efficiency of the cell.

To ensure the quality of the prepared film, the purity of cadmium particles, sulfur particles, and cadmium chloride particles is above 99.999%.

The dispersant can be any suitable solvent, such as organic solvents. Preferably, the dispersant is 1,2-propanediol or 1,3-propanediol. The dispersant may be about 20%-40% of the total weight of the source material.

The coating method can be any technique known to those skilled in the art. For example, the method can be a slurry coating, a silk screen coating technique, and so on. Preferably, silk screen printing is adopted.

Preferably, the slurry forms a coating layer of a thickness of between about 30 and about 400 μm on the first substrate. More preferably, the coating layer is about 100 to about 200 μm.

The drying step is performed under a temperature of between about 100 and about 250° C. Preferably the coating layer is dried at about 150 to about 200° C. for 5-6 hours.

In the present disclosure, cadmium chloride particles, cadmium particles, and sulfur particles are mixed uniformly to form a slurry. In the coating layer, the source material particles are uniform and compacted. The coating layer is uniformly heated. Even if it is reused, the quality will remain the same, pinholes may not appear, and dissipation is also decreased to a great extent. Therefore the film will be even, and the utilization rate of the source material is increased accordingly.

In addition, as the particles in the source material coating layer are compacted, heat is also transferred uniformly. Therefore, the phenomenon that the source material at the center tends to accumulate heat while the edge portion tends to dissipate the heat may be ameliorated or eliminated. As a result, the prepared source material coating may effectively avoid the problems of the cadmium sulfide film prepared according to the conventional CSS method.

In one embodiment of the present disclosure, the graphite plate 2 may be a highly pure graphite plate with an area of 210 mm×210 mm.

The second substrate 4 can be any suitable material. In one embodiment of the disclosure, it is a glass plate.

The chamber has a pressure of about 10⁻³−10³ Pa. According to one embodiment of the disclosure, the pressure is between about 10 and about 100 Pa.

The protective gas is one or more selected from inert gases and nitrogen. For example, it may be selected from the group consisting of He, Ar, N₂, and combinations thereof.

According to one embodiment of the disclosure, oxygen gas is added into the protective gas. Oxygen gas may help to accelerate the growth of crystals and enhance the crystallinity of cadmium sulfide.

Preferably, the oxygen gas has a volume percentage of between about 50% and about 80% in the protective gas. According to one embodiment of the disclosure, the volume percentage is between about 50% and about 70%.

Preferably, the distance between the coating layer of source material and the second substrate is between about 2 and about 10 mm. According to one embodiment of the disclosure, it is between about 2 and about 4 mm.

When increasing the temperature from room temperature to the sublimation temperature, the temperature increasing rate is about 40-150° C./min. According to one embodiment of the disclosure, the temperature increasing rate is about 80-100° C./min.

During the heating and depositing processes, the temperature of the first substrate is about 500-650° C., preferably about 560-600° C. The temperature of the second substrate is about 400-550° C., preferably about 500-520° C.

According to one embodiment of the disclosure, after deposition, the temperature is maintained at between about 300 and about 450° C. for 10-40 minutes.

The step of sublimation and the step of annealing may be performed in the same device, i.e., the CSS device.

According to the method in the present disclosure, the cadmium sulfide film has a thickness of about 60-200 nm. Preferably, the thickness is about 80-120 nm.

The method for preparing cadmium sulfide films will be described in conjunction with following embodiments.

### Example 1

### Preparing the Evaporation Source

Cadmium particles and sulfur particles are mixed according to a molar ratio of about 1:1.1. 95 g mixture and 5 g cadmium chloride particles are added into 20 g propanediol. The mixture is grinded to form a slurry.

The slurry is then coated onto the surface of the bottom graphite plate 2 with an area of about 210 mm×210 mm. Then it is dried under about 150° C. for 5 hours to form a source material coating layer with a thickness of about 100 μm.

Closed Space Sublimation.

The coated plate is placed into a CSS device. The distance between the coating layer and the second substrate is adjusted to be 4 mm. Then a mixture of Ar and oxygen gas with a volume ratio of 1:1 is pumped into the device. The gas pressure is about 100 Pa.

The coated plate is heated to about 580° C. at a temperature increasing rate of about 80° C./min.

The temperature of the second substrate is about 500° C. The thickness of the cadmium sulfide film is controlled to be 100 nm via controlling the deposition time.

Annealing.

After the material is deposited onto the second substrate, the temperature of the film is maintained at about 400° C. for 10-40 minutes.

### Example 2

The only difference from example 1 is: 99 g mixture of cadmium particles and sulfur particles, and 1 g cadmium chloride particles are added into 30 g propanediol. The mixture is then grinded to form a slurry.

### Example 3

The only difference from example 1 is: 90 g mixture of cadmium particles and sulfur particles, and 10 g cadmium chloride particles are added into 40 g propanediol. The mixture is then grinded and mixed to form the slurry.

### Example 4

The only difference from example 1 is: the cadmium particles and sulfur particles are mixed according to a molar ratio of 1:1 to form a mixture. The rest part of the example is the same as example 1.

### Example 5

The only difference from example 1 is: cadmium sulfide particles with the same weight is used instead of the particles mixture, the rest part of the example is the same as example 1.

### Comparative Example 1

Cadmium sulfide particles (purity is about 99.999%) are uniformly disposed onto the surface of the bottom pure graphite plate with an area of about 210 mm×210 mm. The coated plate is placed into a CSS device. The distance between the coating layer and the second substrate is adjusted to be about 4 mm. Then a mixture of Ar and oxygen gas at a volume ratio of 1:1 is pumped into the device. The gas pressure is about 100 Pa.

The container is heated up to 580° C. at a temperature increasing rate of 100° C./min.

The temperature of the second substrate is about 500° C. The temperature of the coating layer is about 580° C. The thickness of the cadmium sulfide film is controlled to be 100 nm via controlling the deposition time. After deposition of cadmium sulfide, a layer of cadmium chloride with a thickness of 100 nm is deposited on the surface of cadmium sulfide and then it is annealed in the air under 400° C. for 30 min.

Performance Test

Film thickness testing: Tencor Alpha-Step 500 is used to measure the thickness of the films.

Visible light transmittance: SHIMADZU UV-3150 UV vis NIR spectrometer is adopted to perform the test.

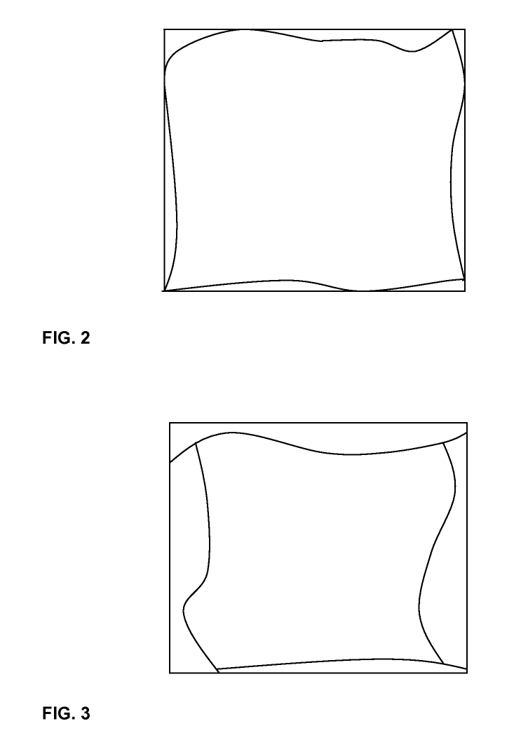

FIG. 2 shows a thickness distribution graph of a cadmium sulfide film prepared by the method according to one embodiment of the disclosure. In the area within the curve shown in FIG. 2, the film thickness distribution is uniform. The film has a thickness of about 100-105 nm. In the area outside the curve, the film thickness distribution is not uniform, and the thickness is about 90-100 nm. FIG. 3 is a distribution map of the thickness of the cadmium sulfide film prepared in comparative example 1. In the area within the curve, the film thickness distribution is uniform, the film has a thickness of about 100-107 nm; outside of the curve, the film thickness distribution is not uniform, and the thickness is about 85-100 nm.

TABLE 1

| | Utilization Rate of | Visible Light |
|---|---|---|
| | Source Material | Transmittance |
| Example 1 | 51.3 | 78 |
| Example 2 | 52.1 | 76 |
| Example 3 | 50.6 | 76 |
| Example 4 | 49.8 | 78 |
| Example 5 | 51.1 | 73 |
| Comparative Example | 12.5 | 72 |

From Table 1, we can see that the utilization rate of source material is enhanced relative to the comparative example. Meanwhile the visible light transmittance is also improved.

Further, the step of annealing in the present method is achieved by maintaining the temperature for a predetermined time, which decreases the request for additional devices and reduces working processes. Also, the present method may improve the utilization rate of the source material.

Many modifications and other embodiments of the present disclosure will come to mind to one skilled in the art to which the present disclosure pertains having the benefit of the teachings presented in the foregoing description. It will be apparent to those skilled in the art that variations and modifications of the present disclosure can be made without departing from the scope or spirit of the present disclosure. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A method for preparing a cadmium sulfide film, comprising:
providing a slurry comprising a dispersant, cadmium particles and sulfur particles;
coating a first substrate with the slurry;
heating the first substrate to produce a vapor; and
depositing the vapor on a second substrate to form a cadmium sulfide film.

2. The method of claim 1, wherein the molar ratio of cadmium to sulfur is between about 1:1 and about 1:1.1.

3. The method of claim 1, wherein the slurry further comprises cadmium chloride particles.

4. The method of claim 3, wherein the cadmium chloride is about 1-10% of the total weight of the slurry.

5. The method of claim 1, wherein the dispersant is selected from the group consisting of 1,2-propanediol, 1,3-propanediol, and combinations thereof.

6. The method of claim 1, wherein the slurry forms a coating layer with a thickness of about 30-400 μm on the first substrate.

7. The method of claim 1, wherein the cadmium sulfide film has a thickness of about 60-200 nm.

8. The method of claim 1, wherein the distance between the coating layer and the second substrate is between about 2 and about 10 mm.

9. The method of claim 1, wherein during at least a portion of the heating and depositing steps, the first substrate is heated to a temperature of between about 500 and about 650° C.; and the second substrate is heated to a temperature of between about 400 and about 550° C.

10. The method of claim 1, wherein the heating is carried out under a pressure of between about 10⁻³ and about 10³ Pa.

11. The method of claim 1, wherein the heating is carried out in the presence of a protective gas.

12. The method of claim 11, wherein the protective gas is selected from the group consisting of He, Ar, N₂, and combinations thereof.

13. The method of claim 11, wherein the protective gas comprises oxygen gas.

14. The method of claim 13, wherein the oxygen gas has a volume percentage of between about 50% and about 80%.

15. A method for preparing a cadmium sulfide film, comprising:
providing a slurry comprising a dispersant, cadmium particles and sulfur particles;
coating a first substrate with the slurry to form a coating layer;
drying the coating layer;
heating the first substrate to produce a vapor;
depositing the vapor onto a second substrate to form a cadmium sulfide film; and
maintaining the cadmium sulfide film at a predetermined temperature thereby annealing the cadmium sulfide film.

16. The method of claim 15, wherein the cadmium sulfide film is maintained at a temperature of between about 300 and about 450° C.

17. The method of claim 16, wherein the cadmium sulfide film is maintained at the temperature for about 10 to about 40 minutes.

18. The method of claim 15, wherein the drying step is performed under a temperature of between about 100 and about 250° C.

19. The method of claim 18, wherein the coating layer is dried for between about 5 and 6 hours.

20. A method for preparing a cadmium sulfide film, comprising:
providing a slurry comprising a dispersant, cadmium particles, sulfur particles, and cadmium chlorides particles;
coating a first substrate with the slurry to form a coating layer;
drying the coating layer;
heating the first substrate to produce a vapor;
depositing the vapor onto a second substrate to form a cadmium sulfide film; and
maintaining the cadmium sulfide film at a predetermined temperature thereby annealing the cadmium sulfide film.
